(19) United States
(12) Patent Application Publication
(10) Pub. No.: US 2017/0062703 A1
(43) Pub. Date: Mar. 2, 2017

(54) MAGNETO-ELECTRIC TRANSDUCER AND METHOD FOR MANUFACTURING THE SAME

(71) Applicant: ROHM CO., LTD., Kyoto (JP)

(72) Inventors: Satoshi NAKAGAWA, Kyoto (JP); Minoru MURAYAMA, Kyoto (JP)

(73) Assignee: ROHM CO., LTD., Kyoto (JP)

(21) Appl. No.: 15/239,444

(22) Filed: Aug. 17, 2016

(30) Foreign Application Priority Data
Sep. 1, 2015 (JP) 2015-172299

(51) Int. Cl. H01L 43/04; H01L 43/14; G01R 33/07; H01L 43/06

(52) U.S. Cl. CPC H01L 43/04; H01L 43/065; H01L 43/14; G01R 33/07

(57) ABSTRACT

A magneto-electric transducer includes: a substrate; a magnetic sensitive layer formed on the substrate; and a pair of input terminals and a pair of output terminals, which are electrically connected to the magnetic sensitive layer, wherein the magnetic sensitive layer includes a longitudinally extending input side region an output side region extending in a direction crossing the input side region, when viewed from top, wherein the output side region includes a first output side region protruding from one side of the input side region and a second output side region protruding from the other side of the input side region, and wherein the first output side region and the second output side region are configured to be asymmetrical with respect to arrangement of the input side region.

### CROSS-REFERENCE TO RELATED APPLICATION

This application is based upon and claims the benefit of priority from Japanese Patent Application No. 2015-172299, filed on Sep. 1, 2015, the entire contents of which are incorporated herein by reference.

### TECHNICAL FIELD

The present disclosure relates to a magneto-electric transducer and a method for manufacturing the same.

### BACKGROUND

As one example of a magneto-electric transducer, a Hall element is known. Because of its ability to convert a magnetic signal to an electrical signal, the Hall element is being used in a wide range of fields including current sensors, motor rotation angle detecting sensors, etc. In the related art, there has been proposed a Hall element including a substrate and a magnetic sensitive portion (magnetic sensitive layer) which is formed on the substrate and has a cross shape when viewed from top.

In general, an unbalanced voltage (or offset voltage) of a magneto-electric transducer is controlled around 0V and accordingly the temperature characteristic of the unbalanced voltage is distributed near 0V. In other words, the temperature characteristic of the unbalanced voltage is generally distributed between a positive region and a negative region around 0V and. When the temperature characteristic of the unbalanced voltage is distributed between a positive region and a negative region around 0V, it may be difficult to control the magneto-electric transducer when managing and controlling an output with respect to an input.

### SUMMARY

The present disclosure provides some embodiments of a magneto-electric transducer which can be easily controlled by distributing the temperature characteristic of an unbalanced voltage to fall within a desired range. Further, the present disclosure provides some embodiments of a magneto-electric transducer which can realize a high precision of detection. Further, the present disclosure provides some embodiments of a method for manufacturing the magneto-electric transducer.

According to one embodiment of the present disclosure, a magneto-electric transducer includes: a substrate; a magnetic sensitive layer formed on the substrate; and a pair of input terminals and a pair of output terminals, which are electrically connected to the magnetic sensitive layer. The magnetic sensitive layer includes a longitudinally extending input side region an output side region extending in a direction crossing the input side region, when viewed from top. The output side region includes a first output side region protruding from one side of the input side region and a second output side region protruding from the other side of the input side region. The first output side region and the second output side region are configured to be asymmetrical with respect to arrangement of the input side region.

With this configuration, it is possible to distribute the temperature characteristic of an unbalanced voltage to fall within a desired range, e.g., one of a positive range and a negative range. Thus, it is possible to prevent the temperature characteristic of the unbalanced voltage from being distributed between a positive region and a negative region around 0V, thereby providing the magneto-electric transducer which may be easily controlled. In addition, it is possible to provide the magneto-electric transducer which is capable of realizing the high precision of detection. In the magneto-electric transducer, the first output side region and the second output side region may be formed to be deviated from each other in the longitudinal direction of the input side region, thereby being asymmetrical. With this configuration, the first output side region and the second output side region are formed to be not line-symmetrical with respect to the arrangement of the input side region, it is possible to distribute the temperature characteristic of the unbalanced voltage to fall within a desired range. For example, such a magneto-electric transducer may be manufactured according to a method for manufacturing a magneto-electric transducer, including:

(a) forming a conductive layer on the substrate by depositing a conductive material on the substrate;

(b) forming a mask, which selectively covers the conductive layer, on the conductive layer such that the first output side region and the second output side region are formed to be deviated from each other in the longitudinal direction of the input side region; and

(c) forming the magnetic sensitive layer by removing an unnecessary portion of the conductive layer through the mask.

With this method, simply by changing the layout of the mask used so far to form a magnetic sensitive layer, it is possible to form the first output side region and the second output side region at positions deviated from each other in the longitudinal direction of the input side region. Therefore, it is possible to manufacture the magneto-electric transducer which may be easily controlled and may realize a high precision of detection without increase in the number of processes.

In the magneto-electric transducer, the first output side region and the second output side region may be formed to have different shapes, thereby being asymmetrical. The first output side region and the second output side region may be formed to have different areas when viewed from top, thereby being asymmetrical. In addition, the first output side region and the second output side region may be formed to have different widths when viewed from top, thereby being asymmetrical. In addition, the first output side region and the second output side region may be asymmetrical by forming a notched portion in one of the first output side region and the second output side region.

With these configurations, the first output side region and the second output side region are formed in different shapes of various aspects to be asymmetrical with respect to the arrangement of the input side region, it is possible to shift and distribute the temperature characteristic of the unbalanced voltage from a distribution near 0V to a desired range in a positive region or a negative region. For example, such magneto-electric transducers may be manufactured according to a method for manufacturing a magneto-electric transducer, including:

(d) forming a conductive layer on the substrate by depositing a conductive material on the substrate;

(e) forming a mask, which selectively covers the conductive layer, on the conductive layer such that the first output side region and the second output side region are formed to have different shapes; and

(f) forming the magnetic sensitive layer by removing an unnecessary portion of the conductive layer through the mask.

With this method, simply by changing the layout of the mask used so far to form a magnetic sensitive layer, it is possible to form the first output side region and the second output side region arranged asymmetrically with respect to the arrangement of the input side region. Therefore, it is possible to manufacture the magneto-electric transducer which may be easily controlled and may realize a high precision of detection without increase in the number of processes.

In the magneto-electric transducer, the first output side region and the second output side region may be formed to have different resistances. With this configuration, even by making the first output side region and the second output side region electrically asymmetrical by making the first output side region and the second output side region different from each other in terms of resistance, it is possible to distribute the temperature characteristic of the unbalanced voltage to fall within a desired range.

In the magneto-electric transducer, the first output side region and the second output side region may be formed at different impurity concentrations. With this configuration, even by making the first output side region and the second output side region electrically asymmetrical by making the first output side region and the second output side region different from each other in terms of impurity concentration, it is possible to distribute the temperature characteristic of the unbalanced voltage to fall within a desired range. For example, such a magneto-electric transducer may be manufactured according to a method for manufacturing a magneto-electric transducer, including:

(g) forming a conductive layer on the substrate by depositing a conductive material on the substrate;

(h) selectively injecting impurities into one of regions to serve as the first output side region and the second output side region;

(i) forming a mask, which selectively covers the conductive layer, on the conductive layer such that the first output side region and the second output side region are formed to have different impurity concentrations; and

(j) forming the magnetic sensitive layer by removing an unnecessary portion of the conductive layer through the mask.

In the magneto-electric transducer, the magnetic sensitive layer may include a compound semiconductor doped with n-type impurities. The magnetic sensitive layer may contain InSb, InAs or GaAs as the compound semiconductor. In addition, the magnetic sensitive layer may contain Si as the n-type impurities.

### BRIEF DESCRIPTION OF THE DRAWINGS

FIG. 1 is a plan view of a magneto-electric transducer according to one embodiment of the present disclosure.

FIG. 2 is a sectional view taken along line II-II in FIG. 1.

FIG. 3 is a plan view of a magnetic sensitive layer shown in FIG. 1.

FIG. 4 is a plan view of a magnetic sensitive layer according to a reference example.

FIG. 5 is a plan view of a magnetic sensitive layer according to another embodiment of the present disclosure.

FIG. 6 is a plan view of a magnetic sensitive layer according to another embodiment of the present disclosure.

FIG. 7 is a plan view of a magnetic sensitive layer according to another embodiment of the present disclosure.

FIG. 8A is a sectional view illustrating one process of a method for manufacturing the magneto-electric transducer shown in FIG. 1.

FIG. 8B is a sectional view illustrating a process subsequent to the process of FIG. 8A.

FIG. 8C is a sectional view illustrating a process subsequent to the process of FIG. 8B.

FIG. 8D is a sectional view illustrating a process subsequent to the process of FIG. 8C.

FIG. 8E is a sectional view illustrating a process subsequent to the process of FIG. 8D.

FIG. 8F is a sectional view illustrating a process subsequent to the process of FIG. 8E.

FIG. 8G is a sectional view illustrating a process subsequent to the process of FIG. 8F.

FIG. 8H is a sectional view illustrating a process subsequent to the process of FIG. 8G.

FIG. 8I is a sectional view illustrating a process subsequent to the process of FIG. 8H.

### DETAILED DESCRIPTION

Exemplary embodiments of the present disclosure will now be described in detail with reference to the accompanying drawings.

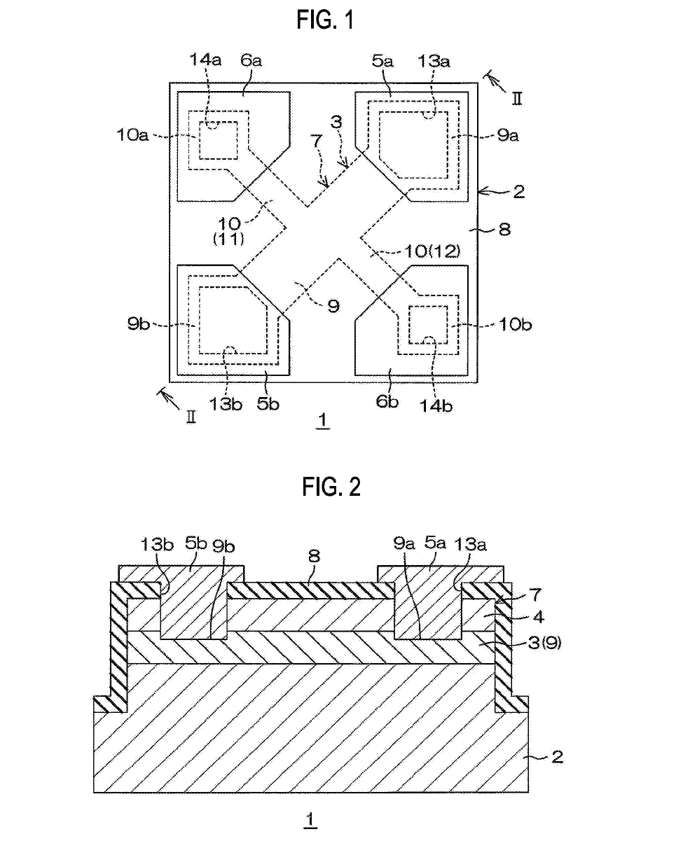

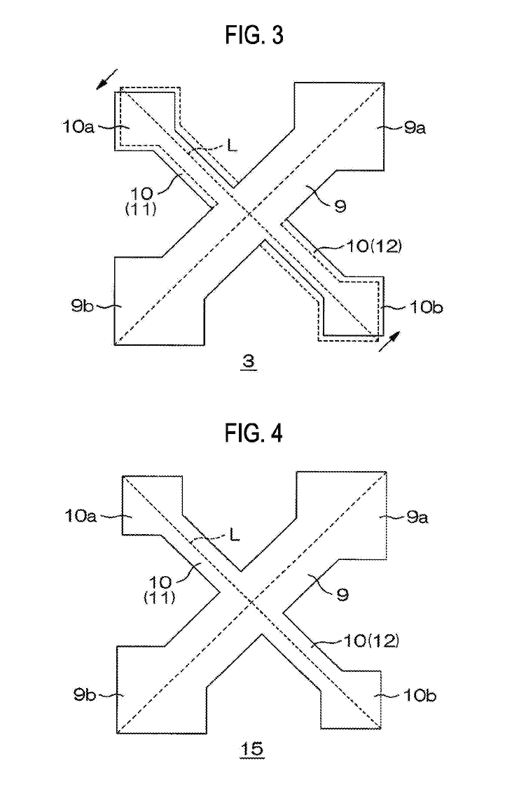

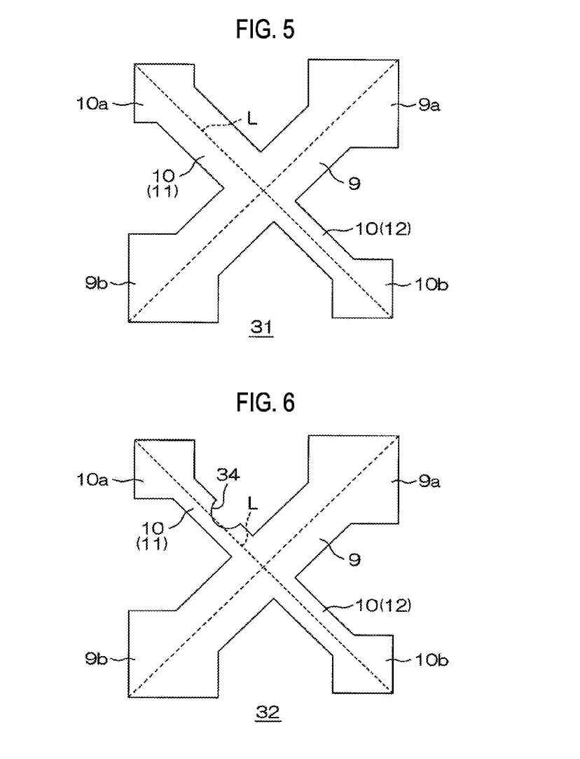

FIG. 1 is a plan view of a Hall element 1, which is one example of a magneto-electric transducer according to one embodiment of the present disclosure. FIG. 2 is a longitudinal sectional view of the Hall element 1, which is taken along line II-II in FIG. 1. FIG. 3 is a plan view of a magnetic sensitive layer 3 shown in FIG. 1.

The Hall element 1 includes a substrate 2, a magnetic sensitive layer 3 formed on the substrate 2, a cap layer 4 formed on the magnetic sensitive layer 3, and a pair of input terminals 5a and 5b and a pair of output terminals 6a and 6b electrically connected to the magnetic sensitive layer 3. In this embodiment, the Hall element 1 has a mesa structure 7 including a portion of the substrate 2, the magnetic sensitive layer 3 and the cap layer 4, which form substantially a cross shape when viewed from top, and includes a protective film 8 formed along the mesa structure 7.

More specifically, the substrate 2 is formed in substantially a rectangular parallelepiped shape and has a main surface of substantially a square shape of about 0.27 mm×0.27 mm when viewed from top, An example of the substrate 2 may include a Si substrate, a SiC substrate, a sapphire single crystal substrate, a compound semiconductor substrate, a semi-insulating substrate having a relatively high resistance, and the like. When the substrate 2 is the compound semiconductor substrate, the substrate 2 may contain InSb, InAs or GaAs. In this embodiment, the substrate 2 includes a semi-insulating compound semiconductor substrate containing GaAs.

The magnetic sensitive layer 3 includes a compound semiconductor added with n-type impurities. The magnetic sensitive layer 3 may contain InSb, InAs or GaAs as the compound semiconductor. The magnetic sensitive layer 3 may contain Si as the n-type impurities. In this embodiment, the magnetic sensitive layer 3 contains GaAs and a positive temperature coefficient of resistance. The term “temperature coefficient of resistance” used herein is defined as ppm (part per million) of an amount of change in resistance per 1 degree C. The thickness of the magnetic sensitive layer 3 may be, e.g., equal to or more than 2000 Å and equal to or less than 15,000 Å.

Referring to FIGS. 1 and 3, the magnetic sensitive layer 3 includes an input side region 9 longitudinally extending, and an output side region 10 longitudinally extending in a direction intersecting with the input side region 9 (i.e., a crosswise intersecting direction) when viewed from top. In this embodiment, the input side region 9 is formed to extend longitudinally along one diagonal of the substrate 2 when viewed from top and has both end portions 9a and 9b which are substantially rectangular when viewed from top. On the other hand, the output side region 10 is formed to extend longitudinally along the other diagonal of the substrate 2 when viewed from top and has both end portions 10a and 10b which are substantially rectangular when viewed from top. In this embodiment, the output side region 10 is formed to be narrower than the input side region 9 when viewed from top and includes a first output side region 11 protruding from one side of the input side region 9 and a second output side region 12 protruding from the other side of the input side region 9.

More specifically, the first output side region 11 protrudes in a direction perpendicular to the longitudinal direction of the input side region 9 from a side face of one side along the longitudinal direction of the input side region 9 in the lengthwise central portion of the input side region 9 and includes one end portion 10a. The second output side region 12 protrudes in a direction perpendicular to the longitudinal direction of the input side region 9 from a side face of the other side along the longitudinal direction of the input side region 9 in the lengthwise central portion of the input side region 9 and includes the other end portion 10b. The first output side region 11 and the second output side region 12 protrude from the input side region 9 at substantially the same extent of protrusion.

This embodiment is characterized in that the first output side region 11 and the second output side region 12 are deviated from each other in the longitudinal direction of the input side region 9 and are formed to be not line-symmetrical with respect to the arrangement of the input side region 9. More specifically, the first output side region 11 is deviated toward the end portion 9b of the input side region 9 from the lengthwise central portion of the input side region 9 along the longitudinal direction, and the second output side region 12 is deviated toward the end portion 9a of the input side region 9 from the lengthwise central portion of the input side region 9 along the longitudinal direction. For example, the first output side region 11 and the second output side region 12 are respectively deviated by 0.2 μm from a transversal line L orthogonally crossing the lengthwise central portion of the input side region 9.

As such, in this embodiment, by setting a predetermined deviation width between the first output side region 11 and the second output side region 12, the first output side region 11 and the second output side region 12 are configured to be not line-symmetrical with respect to the arrangement of the input side region 9. This configuration allows the temperature characteristic of an unbalanced voltage V_{OS} to be distributed to fall within a desired range, e.g., one of a positive range and a negative range.

The term “unbalanced voltage V_{OS}” may be defined as a difference between a first output voltage V_{OUT1} generated at the end portion 10a of the output side region 10 and a second output voltage V_{OUT2} generated at the end portion 10b of the output side region 10 when a predetermined current is flown into the input side region 9 by applying an input voltage Vᵢₙ between both end portions 9a and 9b of the input side region 9 in a state where no magnetic field is applied to the Hall element 1 shown in FIG. 1 (i.e., in s state of non-magnetism) in a plan-view direction of the Hall element 1 (a direction perpendicular to the plane of FIG. 1). In other words, the unbalanced voltage V_{OS} can be expressed as follows.

V_{OS}=V_{OUT1}−V_{OUT2}

The unbalanced voltage V_{OS} is ideally 0V.

However, in actuality, the unbalanced voltage V_{OS} shows a temperature characteristic distribution as described below.

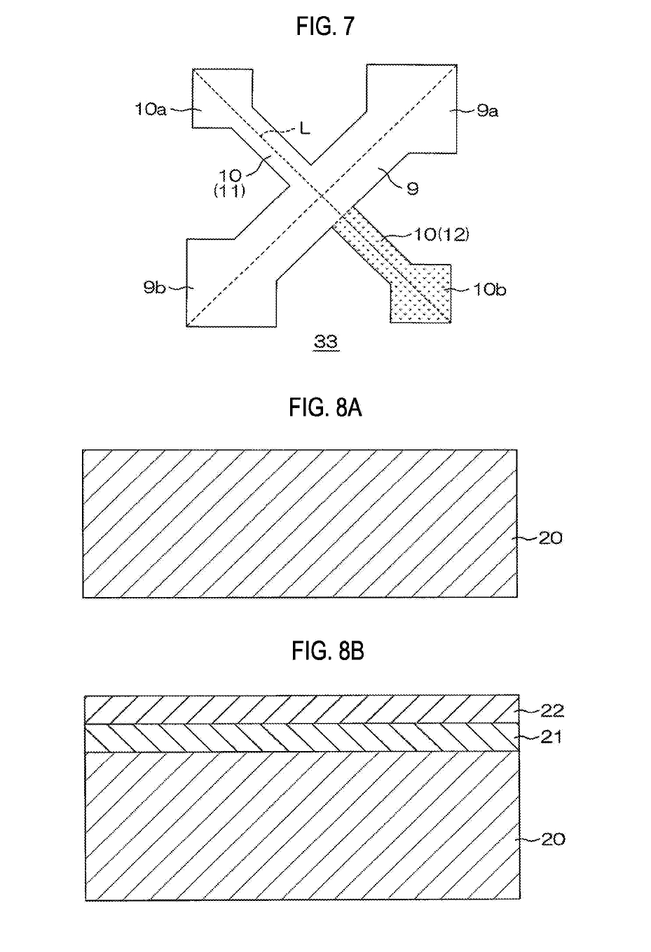

FIG. 4 is a plan view of a magnetic sensitive layer 15 according to a reference example. In the reference example, the magnetic sensitive layer 15 is a conventional magnetic sensitive layer including a first output side region 11 and a second output side region 12 which have the same shape and are formed along the above-mentioned transversal line L line-symmetrically with respect to the arrangement of the input side region 9 when viewed from top. In the magnetic sensitive layer 15 of the reference example, since a resistance bridge as an equivalent circuit of resistance components in the magnetic sensitive layer 15 is configured in balance, the unbalanced voltage V_{OS} would become 0V.

However, in actuality, since the unbalanced voltage V_{OS} is distributed between a positive region and a negative region around 0V, the temperature characteristic of the unbalanced voltage V_{OS} is also distributed around 0V. Therefore, due to an error of measurement of the unbalanced voltage V_{OS}, the temperature characteristic of the unbalanced voltage V_{OS} is also distributed between a positive region and a negative region.

More specifically, since the magnetic sensitive layer 15 of the reference example contains GaAs having a positive temperature coefficient of resistance, when the resistance of the magnetic sensitive layer 15 increases with increase in temperature, the unbalanced voltage V_{OS} increases in proportion to the increase in resistance according to the Ohm′ law in constant current driving. In other words, the temperature characteristic of the unbalanced voltage V_{OS} would have the same sign as the unbalanced voltage V_{OS}.

For example, assuming that a value of the unbalanced voltage V_{OS} is 0.5 mV at 25 degrees C. and 0.55 mV at 65 degrees C., a variation of the unbalanced voltage V_{OS} per 1 degree C. before and after the temperature rise becomes a positive value of 1.25 μV/° C. and the unbalanced voltage V_{OS} has the positive temperature characteristic. On the contrary, assuming that a value of the unbalanced voltage V_{OS} is −0.5 mV at 25 degrees C. and −0.55 mV at 65 degrees C., a variation of the unbalanced voltage V_{OS} per 1 degree C. before and after the temperature rise has a negative value of −1.25 μV/° C. and the unbalanced voltage V_{OS} has the negative temperature characteristic.

However, while the value of the unbalanced voltage V_{OS} is 0.5 mV at 25 degrees C. and 0.55 mV at 65 degrees C., there may be a case where a measurement error exceeding −0.05 mV occurs and the unbalanced voltage V_{OS} is less than 0.5 mV at 65 degrees C. In this case, the variation of the unbalanced voltage V_{OS} per 1 degree C. before and after the temperature rise becomes negative, such that the unbalanced voltage V_{OS} is measured as if the unbalanced voltage V_{OS} has the negative temperature characteristic despite of its positive temperature characteristic.

In this way, in the magnetic sensitive layer 15 of the reference example, although the first output side region 11 and the second output side region 12 are configured to be symmetrical with respect to the arrangement of the input side region 9, the unbalanced voltage V_{OS} does not actually become 0V but is distributed between a positive region and a negative region around 0V. On that account, the temperature characteristic of the unbalanced voltage V_{OS} is also distributed between a positive region to a negative region around 0V, which may result in inversion of the sign of the temperature characteristic of the unbalanced voltage V_{OS}. Therefore, the magnetic sensitive layer 15 of the reference example has a problem of difficulty in control of the Hall element 1 when managing and controlling an output with respect to an input.

In contrast, in the magnetic sensitive layer 3 of this embodiment, the first output side region 11 and the second output side region 12 are intentionally formed to be deviated from each other in the longitudinal direction of the input side region 9 such that the first output side region 11 and the second output side region 12 are configured to be not line-symmetrical with respect to the arrangement of the input side region 9. In other words, in this embodiment, a resistance bridge as an equivalent circuit of resistance components in the magnetic sensitive layer 3 is configured to be unbalanced.

Thus, since the unbalanced voltage V_{OS} may be distributed to fall within a desired range, e.g., one of a positive range and a negative range, the temperature characteristic of the unbalanced voltage V_{OS} may be also distributed to fall within a desired range, e.g., one of a positive range and a negative range. As a result, it is possible to prevent the temperature characteristic of the unbalanced voltage V_{OS} from being distributed between a positive region and a negative region around 0V.

For example, assuming that the unbalanced voltage V_{OS} at 25 degrees C. is an initial value V_{OS1}, the initial value V_{OS1} may be set to a predetermined value at which the sign of the temperature characteristic of the unbalanced voltage V_{OS} is not inverted even when there occurs a measurement error. For example, if the unbalanced voltage V_{OS} at 65 degrees C. is 1.092×V_{OS1} and the measurement error is ±0.1 mV or so, the initial value V_{OS1} may be set to meet the relationship of 1.092×V_{OS1}>2×0.1 mV. That is, when the initial value V_{OS1} is set to meet the relationship of V_{OS1}>0.1832 mV, the unbalanced voltage V_{OS} at 65 degrees C. exceeds 0.2 mV, thereby making it possible to effectively prevent the sign of the temperature characteristic of the unbalanced voltage V_{OS} from being inverted due to the measurement error.

Further, when a deviation σ of a variation distribution exists in the unbalanced voltage V_{OS} when a predetermined current is flown into the input side region 9, the initial value V_{OS1} of the unbalanced voltage V_{OS} is set to a predetermined value in consideration of the deviation σ. For example, from the relationship between the deviation σ and the above-mentioned V_{OS1}>0.1832 mV, the initial value V_{OS1} may be set to meet the relationship of V_{OS1}>0.1832+σ×α (α>0). For example, if the deviation σ is 0.6 mV and α is 5, the initial value V_{OS1} is about 3.183 mV. Therefore, when the first output side region 11 and the second output side region 12 are configured to be asymmetrical with respect to the arrangement of the input side region 9 so as to obtain the unbalanced voltage V_{OS} which is equal to or more than this initial value V_{OS1}, it is possible to more effectively prevent the sign of the temperature characteristic of the unbalanced voltage V_{OS} from being inverted due to the measurement error.

Referring to FIG. 2 again, the cap layer 4 is formed in a shape matching the magnetic sensitive layer 3 when viewed from top and contains, e.g., an impurity-free compound semiconductor. The cap layer 4 may contain InSb, InAs or GaAs as the compound semiconductor. In this embodiment, h cap layer 4 contains GaAs. The thickness of the cap layer 4 may be, e.g., about 500 Å.

The protective film 8 is, e.g., a nitride film containing SiN. In the protective film 8 and the cap layer 4 are formed a pair of input side contact openings 13a and 13b respectively exposing both end portions 9a and 9b of the input side region 9 and a pair of output side contact openings 14a and 14b respectively exposing both end portions 10a and 10b of the output side region 10. The pair of input side contact openings 13a and 13b and the pair of output side contact openings 14a and 14b are formed to penetrate through the cap layer 4 and further dig into a portion of the magnetic sensitive layer 3. The depth to which the pair of input side contact openings 13a and 13b and the pair of output side contact openings 14a and 14b dig into the magnetic sensitive layer 3 may be, e.g., a depth (=200 Å or more and 1500 Å or less) of about 10% of the thickness of the magnetic sensitive layer 3.

The pair of input terminals 5a and 5b is respectively buried in the pair of input side contact openings 13a and 13b and the pair of output terminals 6a and 6b is respectively buried in the pair of output side contact openings 14a and 14b. The pair of input terminals 5a and 5b forms an Ohmic contact with the input side region 9 in the pair of input side contact openings 13a and 13b. On the other hand, the pair of output terminals 6a and 6b forms an Ohmic contact with the output side region 10 in the pair of output side contact openings 14a and 14b.

The pair of input terminals 5a and 5b and the pair of output terminals 6a and 6b may be formed of one metal film or a laminated film including a plurality of laminated metal films. The pair of input terminals 5a and 5b and the pair of output terminals 6a and 6b may include at least an Au film.

As described above, according to this embodiment, with the magnetic sensitive layer 3 including the first output side region 11 and the second output side region 12 configured to be asymmetrical with respect to the arrangement of the input side region 9, it is possible to prevent the temperature characteristic of the unbalanced voltage V_{OS} from being distributed between a positive region and a negative region around 0V, thereby providing the Hall element 1 which can be easily controlled. In addition, it is possible to provide the Hall element 1 which is capable of realizing the high precision of detection.

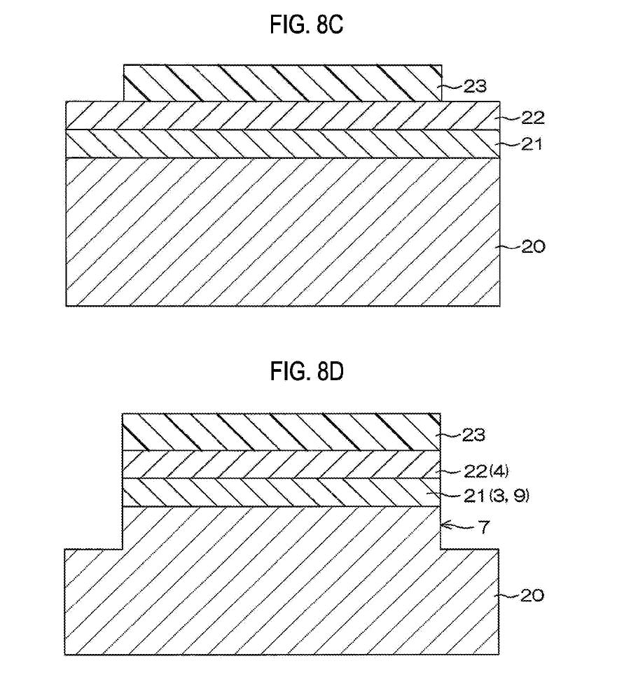

In the embodiments, the magnetic sensitive layer 3 has been illustrated where the first output side region 11 and the second output side region 12 are configured to be asymmetrical with respect to the arrangement of the input side region 9 by setting a predetermined deviation width between the first output side region 11 and the second output side region 12. However, instead of the magnetic sensitive layer 3, one of magnetic sensitive layers 31, 32 and 33 shown in FIGS. 5 to 7 may be used.

FIG. 5 is a plan view of a magnetic sensitive layer 31 according to another embodiment of the present disclosure. In FIG. 5, the elements shown in FIG. 3, etc. described above are denoted by the same reference numerals as those used in FIG. 3, etc., and explanation thereof will not be repeated.

In the magnetic sensitive layer 31, the first output side region 11 and the second output side region 12 are formed along the above-mentioned transversal line L in different shapes with respect to the arrangement of the input side region 9 when viewed from top. More specifically, the first output side region 11 and the second output side region 12 are formed to have different widths when viewed from top, thereby having different areas. Thus, the first output side region 11 and the second output side region 12 are formed to have different resistances.

As described above, in this embodiment, the magnetic sensitive layer 31 includes the first output side region 11 and the second output side region 12 which have shapes asymmetrical with respect to the arrangement of the input side region 9 and are electrically asymmetrical due to different resistances. As a result, since a resistance bridge as an equivalent circuit of resistance components in the magnetic sensitive layer 31 is configured to be unbalanced, it is possible to distribute the temperature characteristic of the unbalanced voltage V_{OS} to fall within a desired range, e.g., one of a positive range and a negative range.

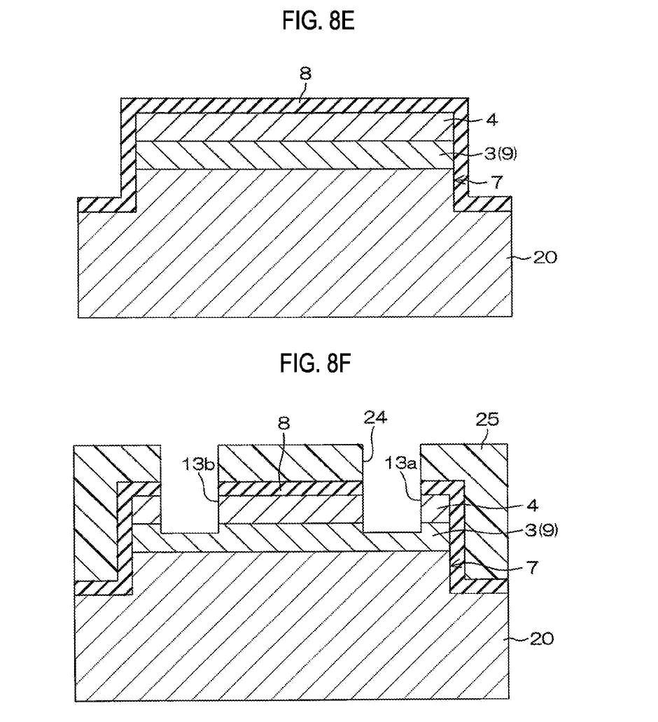

FIG. 6 is a plan view of a magnetic sensitive layer 32 according to another embodiment of the present disclosure. In FIG. 6, the elements shown in FIG. 3, etc. described above are denoted by the same reference numerals as those used in FIG. 3, etc., and explanation thereof will not be repeated.

In the magnetic sensitive layer 32, the first output side region 11 and the second output side region 12 are formed along the above-mentioned transversal line L in different shapes with respect to the arrangement of the input side region 9 when viewed from top. More specifically, the first output side region 11 and the second output side region 12 are formed to have different areas when viewed from top by a notched portion 34 formed in at least one (the first output side region 11 in this embodiment) of the first output side region 11 and the second output side region 12. The number of notched portions 34 may be one or more. Thus, the first output side region 11 and the second output side region 12 are formed to have different resistances.

As described above, in this embodiment, the magnetic sensitive layer 32 includes the first output side region 11 and the second output side region 12 which have shapes asymmetrical with respect to the arrangement of the input side region 9 and are electrically asymmetrical due to different resistances. As a result, since a resistance bridge as an equivalent circuit of resistance components in the magnetic sensitive layer 32 is configured to be unbalanced, it is possible to distribute the temperature characteristic of the unbalanced voltage V_{OS} to fall within a desired range, e.g., one of a positive range and a negative range.

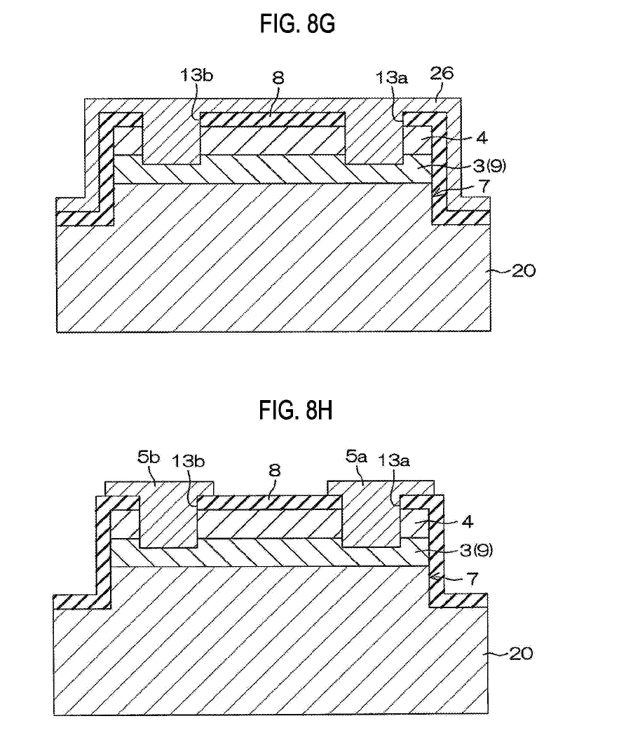

FIG. 7 is a plan view of a magnetic sensitive layer 33 according to another embodiment of the present disclosure. In FIG. 7, the elements shown in FIG. 3, etc. described above are denoted by the same reference numerals as those used in FIG. 3, etc., and explanation thereof will not be repeated.

In the magnetic sensitive layer 33, the first output side region 11 and the second output side region 12 are formed along the above-mentioned transversal line L in the same shape and line-symmetrically with respect to the arrangement of the input side region 9 when viewed from top. In this embodiment, the first output side region 11 and the second output side region 12 are formed at different n-type impurity concentrations, with the n-type impurity concentration of the second output side region 12 set to be higher than the n-type impurity concentration of the first output side region 11. In FIG. 7, the second output side region 12 having the higher n-type impurity concentration is hatched for the purpose of clarity.

Thus, the first output side region 11 and the second output side region 12 are formed to have different resistances. In addition, when the n-type impurity concentration of a portion of one or both of the first output side region 11 and the second output side region 12 is set to be higher than the n-type impurity concentration of the other portions, the first output side region 11 and the second output side region 12 may be formed at different n-type impurity concentrations.

As described above, in this embodiment, the magnetic sensitive layer 33 includes the first output side region 11 and the second output side region 12 which are electrically asymmetrical due to different n-type impurity concentrations (resistances) with respect to the arrangement of the input side region 9. As a result, since a resistance bridge as an equivalent circuit of resistance components in the magnetic sensitive layer 33 is configured to be unbalanced, it is possible to distribute the temperature characteristic of the unbalanced voltage V_{OS} to fall within a desired range, e.g., one of a positive range and a negative range.

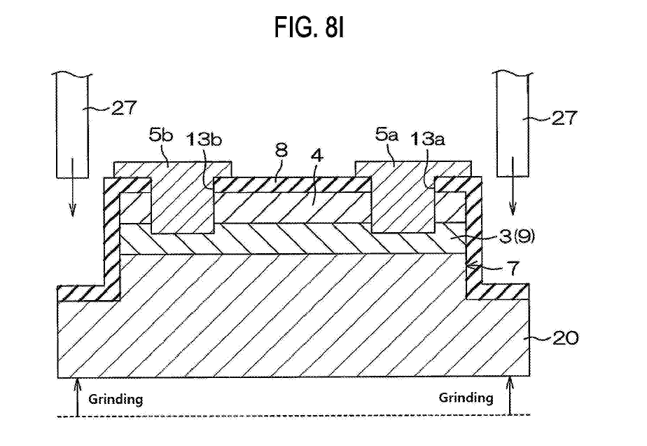

FIGS. 8A to 8I are sectional views illustrating one process of a method for manufacturing the Hall element 1 shown in FIG. 1. FIGS. 8A to 8I are sectional views of the portion corresponding to the above-described FIG. 2.

In manufacturing the Hall element 1, first, as shown in FIG. 8A, a disc-like original substrate 20 containing GaAs, which serves as the original of the substrate 2, is prepared. Subsequently, as shown in FIG. 8B, by epitaxially growing GaAs while doping Si as n-type impurities, a first compound semiconductor layer 21, as one example of a conductive layer of the present disclosure, which serves as the original of the magnetic sensitive layer 3, is formed on the original substrate 20. Subsequently, by epitaxially growing GaAs with no impurity doping, a second compound semiconductor layer 22, which serves as the original of the cap layer 4, is formed on the first compound semiconductor layer 21.

Next, as shown in FIG. 8C, a first resist mask 23 made of, e.g., photosensitive polyimide is applied on the second compound semiconductor layer 22. Subsequently, the first resist mask 23 is selectively exposed and developed, and the first resist mask 23 covering a region where the mesa structure is to be formed is formed on the second compound semiconductor layer 22. At this time, the first resist mask 23 covers the second compound semiconductor layer 22 such that the first output side region 11 and the second output side region 12 are formed to be deviated from each other in the longitudinal direction of the input side region 9 with respect to the magnetic sensitive layer 3 when viewed from top.

Next, as shown in FIG. 8D, unnecessary portions of the second compound semiconductor layer 22, the first compound semiconductor layer 21 and the original substrate 20 are removed by etching (e.g., reactive ion etching) through the first resist mask 23. Thus, the mesa structure 7 including the magnetic sensitive layer 3 and the cap layer 4 having predetermined shapes is formed.

Next, as shown in FIG. 8E, SiN is deposited by, e.g., a CVD method or the like, and the protective film 8 is formed to cover the mesa structure 7 and the original substrate 20 exposed from the mesa structure 7. Subsequently, as shown in FIG. 8F, a second resist mask 25 having selective openings 24 in a region where the pair of input side contact openings 13a and 13b and the pair of output side contact openings 14a and 14b are to be formed is formed on the protective film 8. Subsequently, unnecessary portions of the protective film 8 and the cap layer 4 are removed by etching (e.g., reactive ion etching) through the second resist mask 25. At the time of this etching, a portion of the magnetic sensitive layer 3 is over-etched by, e.g., about 10% of the thickness of the magnetic sensitive layer 3. Thus, the pair of input side contact openings 13a and 13b and the pair of output side contact openings 14a and 14b are formed.

Next, as shown in FIG. 8G, a metal film 26, which contains Au, for filling the pair of input side contact openings 13a and 13b and the pair of output side contact openings 14a and 14b and covering the entire protective film 8 is formed by, e.g., a sputtering method, a deposition method or the like. Subsequently, as shown in FIG. 8H, the metal film 26 is patterned to form the pair of input terminals 5a and 5b and the pair of output terminals 6a and 6b.

Next, as shown in FIG. 8I, the original substrate 20 is grinded, starting from its back side, by, e.g., lapping, CMP or the like, thereby thinning the original substrate 20. Thereafter, the original substrate 20 is cut around the mesa structure 7 by means of a dicing saw 27 or the like, and segments of the Hall element 1 are cut out. Thus, the Hall element 1 is manufactured.

As described above, according to the method of this embodiment, simply by changing the layout of the first resist mask 23 used so far to form the magnetic sensitive layer, it is possible to form the first output side region 11 and the second output side region 12 at positions deviated from each other in the longitudinal direction of the input side region 9. Therefore, it is possible to manufacture the Hall element 1 which can be easily controlled and can realize the high precision of detection without increase in the number of processes.

In addition, when the magnetic sensitive layer 31 shown in FIG. 5 is formed, the layout of the first resist mask 23 may be simply changed in the above-described process of FIG. 8C. In other words, the first resist mask 23 may be formed to cover the second compound semiconductor layer 22 such that the first output side region 11 and the second output side region 12 are formed to have different widths. Thus, the magnetic sensitive layer 31 shown in FIG. 5 can be formed.

In addition, when the magnetic sensitive layer 32 shown in FIG. 6 is formed, the layout of the first resist mask 23 may be simply changed in the above-described process of FIG. 8C. That is, the first resist mask 23 may be formed to cover the second compound semiconductor layer 22 such that the notched portion 34 is formed in one of the first output side region 11 and the second output side region 12. Thus, the magnetic sensitive layer 32 shown in FIG. 6 can be formed.

In addition, when the magnetic sensitive layer 33 shown in FIG. 7 is formed, a process of selectively injecting additional n-type impurities into one of regions to serve as the first output side region 11 and the second output side region 12 in the first compound semiconductor layer 21 may be added before the process of forming the second compound semiconductor layer 22 after the process of forming the first compound semiconductor layer 21 in the above-described FIG. 8B. This n-type impurity injection may be performed through an ion injection mask selectively covering the first compound semiconductor layer 21.

Thus, in a portion of the first compound semiconductor layer 21 is formed a high concentration region having a n-type impurity concentration higher than that of the other portions thereof. Then, after forming the second compound semiconductor layer 22, in the process of FIG. 8C, the first resist mask 23 to cover the high concentration region may be formed on the second compound semiconductor layer 22 such that the first output side region 11 including the high concentration region or the second output side region 12 including the high concentration region is formed. Thus, the magnetic sensitive layer 33 shown in FIG. 7 can be formed.

While the exemplary embodiments of the present disclosure have been illustrated in the above, the present disclosure may be practiced in different forms.

For example, each of the configurations of the magnetic sensitive layers 31, 32 and 33 shown in FIGS. 5 to 7 may be combined to the configuration of the magnetic sensitive layer 3 according to the above-described one embodiment. In addition, each of the configurations of the magnetic sensitive layers 31, 32 and 33 shown in FIGS. 5 to 7 may be used in proper combination.

In addition, an example of forming the magnetic sensitive layer 3 having the positive temperature coefficient of resistance has been described in the above embodiments. However, the magnetic sensitive layer 3 may be made of a material having a negative temperature coefficient of resistance. In this case, since the resistance decreases with increase in the temperature of the magnetic sensitive layer 3, the temperature characteristic of the unbalanced voltage V_{OS} has a distribution in which the sign of the unbalanced voltage V_{OS} of the magnetic sensitive layer 3 having the positive temperature coefficient of resistance is inverted. Even with this configuration, it is possible to prevent the temperature characteristic of the unbalanced voltage from being distributed between a positive region and a negative region around 0V.

Further, a variety of changes in design may be made within the scope of the present disclosure defined in the appended claims.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A magneto-electric transducer comprising:
a substrate;
a magnetic sensitive layer formed on the substrate; and
a pair of input terminals and a pair of output terminals, which are electrically connected to the magnetic sensitive layer,
wherein the magnetic sensitive layer includes a longitudinally extending input side region an output side region extending in a direction crossing the input side region, when viewed from top,
wherein the output side region includes a first output side region protruding from one side of the input side region and a second output side region protruding from the other side of the input side region, and
wherein the first output side region and the second output side region are configured to be asymmetrical with respect to arrangement of the input side region.

2. The magneto-electric transducer of claim 1, wherein the first output side region and the second output side region are formed to be deviated from each other in the longitudinal direction of the input side region.

3. The magneto-electric transducer of claim 1, wherein the first output side region and the second output side region are formed to have different shapes.

4. The magneto-electric transducer of claim 3, wherein the first output side region and the second output side region are formed to have different areas when viewed from top.

5. The magneto-electric transducer of claim 3, wherein the first output side region and the second output side region are formed to have different widths when viewed from top.

6. The magneto-electric transducer of claim 3, wherein a notched portion is formed in one of the first output side region and the second output side region.

7. The magneto-electric transducer of claim 1, wherein the first output side region and the second output side region are formed to have different resistances.

8. The magneto-electric transducer of claim 1, wherein the first output side region and the second output side region are formed at different impurity concentrations.

9. The magneto-electric transducer of claim 1, wherein the magnetic sensitive layer contains a compound semiconductor doped with n-type impurities.

10. The magneto-electric transducer of claim 9, wherein the magnetic sensitive layer contains InSb, InAs or GaAs as the compound semiconductor.

11. The magneto-electric transducer of claim 9, wherein the magnetic sensitive layer contains Si as the n-type impurities.

12. A method for manufacturing the magneto-electric transducer of claim 2, comprising:
forming a conductive layer on the substrate by depositing a conductive material on the substrate;
forming a mask, which selectively covers the conductive layer, on the conductive layer such that the first output side region and the second output side region are formed to be deviated from each other in the longitudinal direction of the input side region; and
forming the magnetic sensitive layer by removing an unnecessary portion of the conductive layer through the mask.

13. A method for manufacturing the magneto-electric transducer of claim 3, comprising:
forming a conductive layer by depositing a conductive material on the substrate;
forming a mask, which selectively covers the conductive layer, on the conductive layer such that the first output side region and the second output side region are formed to have different shapes; and
forming the magnetic sensitive layer by removing an unnecessary portion of the conductive layer through the mask.

14. A method for manufacturing the magneto-electric transducer of claim 8, comprising:
forming a conductive layer by depositing a conductive material on the substrate;
selectively injecting impurities into one of regions to serve as the first output side region and the second output side region;
forming a mask, which selectively covers the conductive layer, on the conductive layer such that the first output side region and the second output side region are formed to have different impurity concentrations; and
forming the magnetic sensitive layer by removing an unnecessary portion of the conductive layer through the mask.
